(19) United States
(12) Patent Application Publication
(10) Pub. No.: US 2017/0344692 A1
(43) Pub. Date: Nov. 30, 2017

(54) COMPUTER-IMPLEMENTED METHOD OF DESIGNING AN INTEGRATED CIRCUIT

(71) Applicant: SAMSUNG ELECTRONICS CO., LTD., SUWON-SI (KR)

(72) Inventors: SUNG-MIN OH, YONGIN-SI (KR); JONG-KU KANG, SUWON-SI (KR); KWANG-OK JEONG, HWASEONG-SI (KR)

(21) Appl. No.: 15/479,119

(22) Filed: Apr. 4, 2017

(30) Foreign Application Priority Data
May 26, 2016 (KR) 10-2016-0064937

(51) Int. Cl. G06F 17/50; G03F 7/20; H01L 21/768; H01L 23/48

(52) U.S. Cl. CPC G06F 17/5077; H01L 23/481; G03F 7/70483; G06F 17/5009; H01L 21/768

(57) ABSTRACT

A computer-implemented method of designing an integrated circuit includes: receiving first data that includes a plurality of resistance values with respect to a via in the integrated circuit, wherein each of the plurality of resistance values is defined based on at least one of a width of a conductive line connected to the via or a space between the conductive line and an adjacent conductive line; receiving second data that includes physical characteristics of a layout of the integrated circuit; and extracting, by using a processor, a via resistance based on the layout from the plurality of resistance values based on the first and second data.

### CROSS-REFERENCE TO RELATED APPLICATION

This application claims priority under 35 U.S.C. §119 from, and the benefit of, Korean Patent Application No. 10-2016-0064937, filed on May 26, 2016 in the Korean Intellectual Property Office, the contents of which are herein incorporated by reference in their entirety.

### BACKGROUND

Embodiments of the inventive concept are directed to an integrated circuit, and more particularly, to a computer-implemented method of designing an integrated circuit, and a method of manufacturing a semiconductor device.

Designing a semiconductor integrated circuit is a process of converting a behavior model with respect to a chip, which describes operations to be performed by a semiconductor system, into a specific structural model that describes connections between components thereof. As semiconductor process technology has developed, process precision has increased. That is, the metal pitch of integrated circuits has decreased. Accordingly, a self-aligned via (SAV) formation process is used to form vias. As via size has also decreased, variations in via resistance due to changes in critical dimensions of the vias has gradually increased.

According to the related art, a via resistance is described as a single fixed value. In detail, a worst case via resistance of a metal minimum critical dimensions (CDs) is applied to every via. Here, when a via is formed using a self-aligned via (SAV) process, despite a change in a via CD due to a change in a metal CD, which changes the via resistance, the worst case via resistance is applied, which decreases the accuracy of a simulation result. In addition, the SAV process can cause differences in via resistance due to a space between a metal and a dummy metal. A worst case via resistance is applied despite changes in via resistance due to the change in the space of the metals, which decreases the accuracy of simulation results.

### SUMMARY

According to an embodiment of the inventive concept, there is provided a computer-implemented method of designing an integrated circuit, the method including: receiving first data that includes a plurality of resistance values of a via in the integrated circuit, wherein each of the plurality of resistance values is defined based on at least one of a width of a conductive line connected to the via and a space between the conductive line and an adjacent conductive line; receiving second data that includes physical characteristics of a layout of the integrated circuit; and extracting, by a processor, a via resistance of the layout from the plurality of resistance values based on the first and second data.

According to another embodiment of the inventive concept, there is provided a computer-implemented method of designing an integrated circuit, the method including: defining, by a processor, a plurality of characteristic values with respect to a parasitic element of a via based on physical characteristics of a conductive line connected to the via in the integrated circuit; generating a parasitic element file of the via, wherein the parasitic element file includes the plurality of characteristic values; and outputting the parasitic element file.

According to another embodiment of the inventive concept, there is provided a computer-implemented method of designing an integrated circuit, the method including: receiving parameter data that includes a plurality of characteristic values with respect to one via in the integrated circuit; receiving layout data that includes physical or geometric characteristics regarding various patterns included in a layout of integrated circuit, wherein the layout data includes a width value and a space value of a conductive line included in the layout; extracting, by a processor, a parasitic element from the parameter data and the layout data; and outputting a parasitic description file that includes parasitic resistances and parasitic capacitances of each of the conductive lines and vias that form one net of an integrated circuit.

### BRIEF DESCRIPTION OF THE DRAWINGS

FIG. 1 is a flowchart of a method of manufacturing a semiconductor device, according to an embodiment of the inventive concept.

FIG. 2 is a schematic structural diagram of a routing structure included in an integrated circuit according to an embodiment of the inventive concept.

FIGS. 3 and 4 illustrate integrated circuit design systems according to some embodiments of the inventive concept.

FIG. 5 is a flowchart of an integrated circuit designing method according to an embodiment of the inventive concept.

FIG. 6 is a detailed flowchart of a parasitic extraction operation according to an embodiment of the inventive concept.

FIG, 7 is a detailed flowchart of a timing analysis operation according to an embodiment of the inventive concept.

FIG. 8 is a flowchart of a method of designing an integrated circuit according to an embodiment of the inventive concept.

FIG. 9 illustrates a routing structure included in an integrated circuit according to an embodiment of the inventive concept.

FIG. 10 is a table showing via resistances according to widths and spaces of an upper conductive line and a lower conductive line connected to a via according to an embodiment of the inventive concept.

FIGS. 11A through 11C illustrate integrated circuit layouts according to an embodiment of the inventive concept.

FIG. 12 illustrates a first technology file according to an embodiment of the inventive concept.

FIGS. 13A through 13C illustrate integrated circuit layouts according to an embodiment of the inventive concept.

FIG. 14 illustrates a second technology file according to an embodiment of the inventive concept.

FIG. 15 illustrates a third technology file according to an embodiment of the inventive concept.

FIG. 16 illustrates a device under test (DUT) used in a test operation according to an embodiment of the inventive concept.

FIGS. 17A through 17C illustrate design of experiments (DOE) used in a test operation according to an embodiment of the inventive concept.

FIG. 18 is an integrated circuit layout according to an embodiment of the inventive concept.

FIG. 19 is a block diagram of a storage medium according to an embodiment of the inventive concept.

FIG. 20 is a block diagram of a computing system according to an embodiment of the inventive concept.

### DETAILED DESCRIPTION OF THE EMBODIMENTS

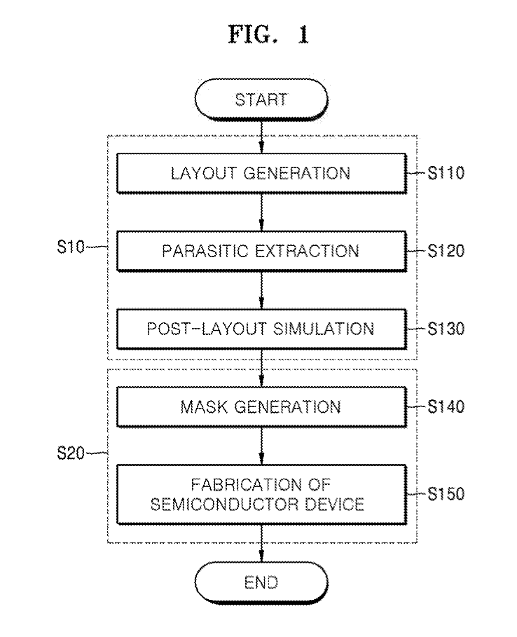

FIG. 1 is a flowchart of a method of manufacturing a semiconductor device, according to an embodiment of the inventive concept.

Referring to FIG. 1, a method of manufacturing a semiconductor device according to a present embodiment is divided into an integrated circuit designing operation S10 and an integrated circuit manufacturing operation S20. The integrated circuit designing operation S10 includes operations S110 through S130, in which a layout of an integrated circuit is designed using a tool for designing an integrated circuit. In this case, the tool for designing the integrated circuit may be a program that includes a plurality of instructions executed by a processor. Thus, the integrated circuit designing operation S10 can be referred to as a computer-implemented method for integrated circuit design. In the integrated circuit manufacturing operation S20, a semiconductor device is manufactured according to an integrated circuit based on a designed layout, and is performed by a semiconductor process module.

According to embodiments, an integrated circuit can be defined by a plurality of cells. in detail, an integrated circuit can be designed using a cell library that includes characteristic information regarding a plurality of cells. In the cell library, cell names, dimensions, gate widths, pins, delay characteristics, leakage current, critical voltages, functions of cells are defined. According to embodiments of the inventive concept, a cell library is a standard cell library. A standard cell library typically includes information such as layout information and timing information of a plurality of standard cells, and is typically stored in a computer-readable storage medium.

According to embodiments, in operation S110, a layout of an integrated circuit is generated. According to an embodiment, a layout is generated by placing and routing (P&R) standard cells using a standard cell library. Thus, operation S110 can be referred to as a P&R operation and performed by a processor using a P&R tool. Hereinafter, a layout generating operation will be described in detail.

First, according to embodiments, input data that defines an integrated circuit is received. The input data can be generated from an abstract behaviour definition of an integrated circuit, such as data defined as a Register Transfer Level (RTL), by using a standard cell library. For example, the input data may be a bitstream or a netlist that is generated by synthesizing an integrated circuit defined in a hardware description language (HDL) such as VHSIC Hardware Description Language (VHDL) or Verilog.

Next, according to embodiments, a storage medium that stores the standard cell library is accessed, and standard cells are selected from a plurality of standard cells stored in the standard cell library and routed based on the input data. P&R refers to placing selected standard cells and connecting the placed standard cells to each other. When P&R is completed, the layout of the integrated circuit can be generated.

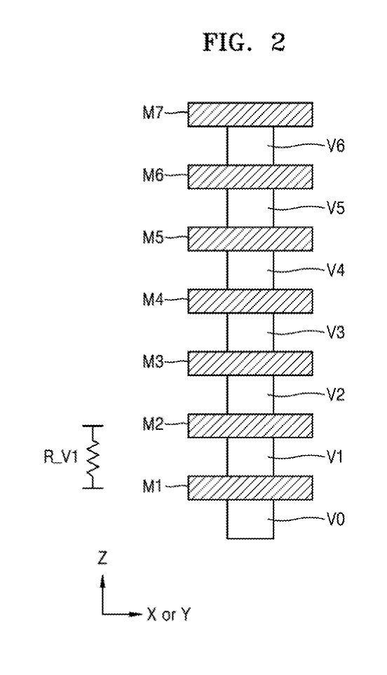

According to embodiments, in operation S120, a parasitic element is extracted. In detail, the parasitic extraction operation refers to extracting a parasitic element, such as a parasitic resistance or a parasitic capacitance, included in the routing structure of the layout generated in operation S110, and can be performed using a parasitic extraction tool. A layout of an integrated circuit includes a routing structure in which a plurality of routing layers are stacked, and each routing layer includes a plurality of patterns. Patterns in routing layers at different levels can be electrically connected to each other through vias formed of a conductive material. The routing layers include conductive materials, such as a metal, and may be referred to as metal layers. However, according to some embodiments of the inventive concept, routing layers may also include a non-metallic conductive material. Hereinafter, operation S120 will be described with reference to both FIGS. 1 and 2.

FIG. 2 is a schematic structural diagram of a routing structure included in an integrated circuit according to an embodiment of the inventive concept.

Referring to FIG. 2, according to embodiments, the routing structure included in the integrated circuit includes a plurality of metal layers M1 through M7 and a plurality of vias V0 through V6, all stacked in a Z-direction. The routing structure provides a path through which an electrical signal or current can flow. One net that indicates an equipotential in an equivalent circuit diagram of an integrated circuit corresponds to one interconnection in a layout of an integrated circuit, and one interconnection corresponds to a routing structure that includes the metal layers M1 through M7 and the vias V0 through V6 that are electrically connected to each other. While seven metal layers and seven vias are illustrated in FIG. 2, a routing structure included in an integrated circuit according to embodiments of the inventive concept are not limited thereto, and can include more or less than six metal layers and six vias.

According to embodiments, each of the vias V0 through V6 electrically connects the metal layers M1 through M7 to each other. For example, a second via V1 is disposed between a first metal layer M1 and a second metal layer M2 to electrically connect the first metal layer M1 and the second metal layer M2. According to embodiments, a via resistance R_V1 is generated between two ends of the second via V1 due to the material of the second via V1, the contact area between the second via V1 and the first metal layer M1, and the contact area between the second via V1 and the second metal layer M2. Similarly, a via resistance can be generated between two ends of each of the first and third through seventh vias V0 and V2 through V6.

According to embodiments, a via resistance is a parasitic resistance not intended by the designer of the integrated circuit, and can cause a signal delay in a signal path in which the via is included. A signal delay caused by a parasitic resistance or a parasitic capacitance is referred to as an interconnect delay. A greater resistance value of a via resistance increases the signal delay, and an increase of a signal delay can cause the integrated circuit to fail to satisfy a designed operating speed of the integrated circuit. Thus, prior to manufacturing the integrated circuit at operation S20, the actual operating speed and a function of a chip can be tested by extracting a parasitic element from a layout and performing simulations based on the extracted parasitic element.

According to a present embodiment, a parasitic element includes a parasitic resistance and a parasitic capacitance of the metal layers M1 through M7 and the vias V0 through V6 in the layout. Hereinafter, operation S120 will be described with reference to an operation of extracting a via resistance, which is the parasitic resistance of a via. However, embodiments of the inventive concept is not limited thereto, and can incorporate operations such as extracting a parasitic capacitance of a via or a parasitic resistance and capacitance of a metal layer in a substantially similar manner.

According to a present embodiment, first data and second data are received. The first data includes a plurality of resistance values defined based on at least one of a width and a space of a metal layer connected to a via, and the second data includes physical information of a layout generated in operation S110. One of the plurality of resistance values included in the first data is extracted as a via resistance based on the second data. As described above, according to a present embodiment, a via resistance is dynamically extracted in operation S120 based on the physical information of the layout.

Referring back to FIG. 1, according to embodiments, in operation S130, a post-layout simulation is performed. In detail, the post-layout simulation is performed by using a netlist that includes an interconnect delay extracted in operation S120. When a result of the simulation performed in operation S130 satisfies design constraints, output data that defines an integrated circuit is provided to a semiconductor process module. The output data may include all layout information of standard cells, that is, pattern information of all layers, such as a Graphic Design System II (GDSII) format, or may include external information of standard cells, such as pins of standard cells, for example, a Library Exchange Format (LEF) or a Milkyway format. On the other hand, when a result of the simulation performed in operation S130 does not satisfy design constraints, operation S110 is performed again.

According to a present embodiment, instead of performing a post-layout simulation by applying a fixed value with respect to a via resistance, a post-layout simulation can be performed by applying a via resistance that is dynamically extracted based on a width or space of a metal layer in the layout. Accordingly, a via resistance that is close to an actual via resistance can be extracted based on the width or space of the metal layer, thereby improving simulation accuracy and securing design margins.

As described above, according to embodiments, the integrated circuit designing operation S10 includes operations S110 through S130 described above. However, embodiments of the inventive concept are not limited thereto, and a method according to an embodiment of the inventive concept may further include other operations that are typical to methods of designing an integrated circuit, such as generating a standard cell library, modifying a standard cell library, or verifying a layout. In addition, operations S110 through S130 may correspond to a back-end design operation included in an integrated circuit design process, and a front-end design operation may be performed prior to operation S110. A front-end design operation may include, for example, determining a design specification, modelling and verifying a behaviour level, designing an RTL, verifying functionality, logic synthesis, and verifying a gate level (or pre-layout simulation).

In operation S140, according to embodiments, a mask is generated based on the layout. In detail, first, optical proximity correction (OPC) may be performed based on the layout. OPC modifies a layout by correcting an error due to optical proximity effects. Next, a mask is manufactured based on the layout as modified by the OPC. According to embodiments, a mask is manufactured using the OPC corrected layout, for example, by using a graphic design system (GDS) to which OPC is applied.

In operation S150, according to embodiments, a semiconductor device is manufactured using the mask. In detail, a semiconductor device is formed on a semiconductor substrate such as a wafer, by performing various semiconductor processes using the mask. For example, a patterning process that uses a mask may be a lithography process. Through a patterning process, a desired pattern can be formed on the semiconductor substrate or a material layer. The semiconductor process may include, for example, a depositing process, an etching process, an ion process, a cleaning process, etc. In addition, the semiconductor process may include a packaging process in which the semiconductor device is mounted on a printed circuit board (PCB) and encapsulated using a sealing member, or a test process in which a semiconductor device or a package is tested.

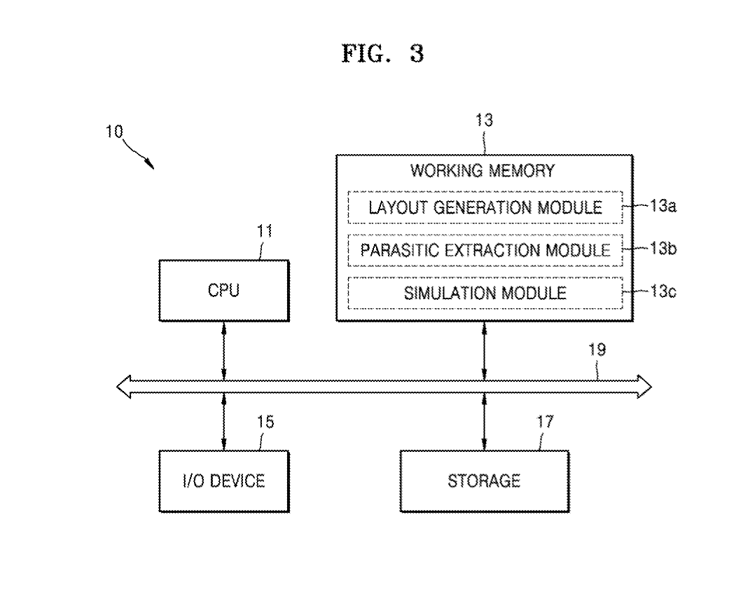

FIG. 3 is a diagram which illustrates an integrated circuit design system 10 according to an embodiment of the inventive concept.

Referring to FIG. 3, according to embodiments, the integrated circuit design system 10 includes a central processing unit (CPU) 11, a working memory 13, an input/output device 15, a storage device 17, and a bus 19. According to a present embodiment, the integrated circuit design system 10 is implemented as an integrated device, and thus is referred to as an integrated circuit designing device. The integrated circuit design system 10 may be a dedicated device for designing an integrated circuit of a semiconductor device, or may be a computer that operates various simulation tools or design tools.

According to embodiments, the CPU 11 is configured to execute instructions to perform at least one of various operations to design an integrated circuit. The CPU 11 can communicate with the working memory 13, the input/output device 15, and the storage device 17 via the bus 19. The CPU 11 can design an integrated circuit by operating a layout generation module 13a, a parasitic extraction module 13b, and a simulation module 13c loaded in the working memory 13.

According to embodiments, the working memory 13 stores the layout generation module 13a, the parasitic extraction module 13b, and the simulation module 13c. The layout generation module 13a, the parasitic extraction module 13b, and the simulation module 13c can be loaded from the storage device 17 to the working memory 13. The working memory 13 may be a volatile memory such as static random access memory (SRAM) or dynamic RAM (DRAM) or a non-volatile memory such as phase-change RAM (PRAM), magnetic RAM (MRAM), resistive RAM (ReRAM), ferroelectric RAM (FRAM) or a NOR flash memory.

According to embodiments, the layout generation module 13a is a program that includes a plurality of instructions to perform layout generating operations, for example, according to operation S110 of FIG. 1. The parasitic extraction module 13b is a program that includes a plurality of instructions to perform parasitic extracting operations, for example, according to operation S120 of FIG. 1. The simulation module 13c is a program that includes a plurality of instructions to perform post-layout simulation operations, for example, according to operation S130 of FIG. 1.

According to embodiments, the input/output device 15 controls user inputs and outputs from user interface devices. For example, the input/output device 15 may include an input device such as a keyboard, a mouse, or a touch pad to receive input data that defines an integrated circuit. Further, the input/output device 15 may include an output device such as a display or a speaker to display a layout generation procedure or a simulation result, etc.

According to embodiments, the storage device 17 stores various types of data related to the layout generation module 13a, the parasitic extraction module 13b, and the simulation module 13c. The storage device 17 may include a memory card, such as MMC, eMMC, SD, MicroSD, etc., a solid state drive, a hard disk drive, etc.

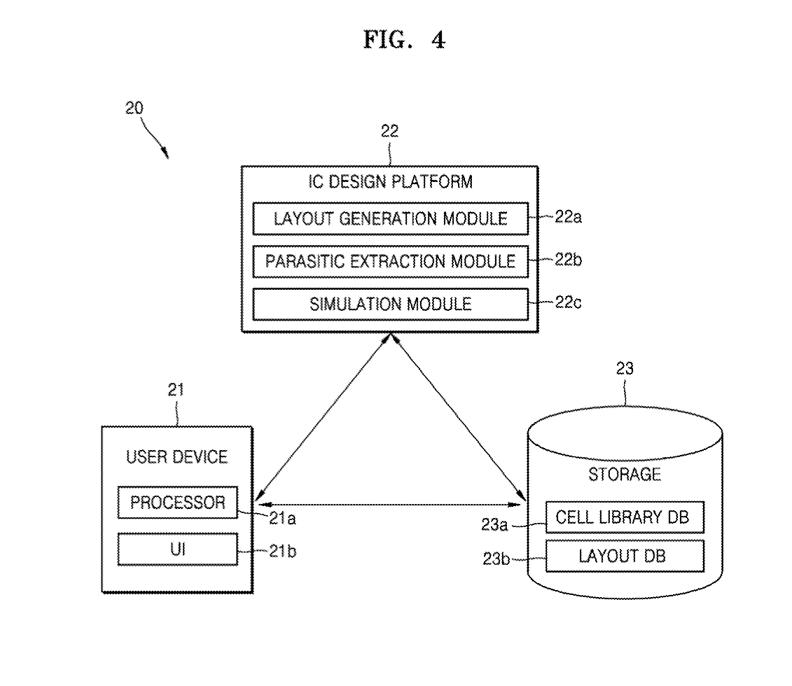

FIG. 4 illustrates an integrated circuit design system 20 according to an embodiment of the inventive concept.

Referring to FIG. 4, according to embodiments, the integrated circuit design system 20 includes a user device 21, an integrated circuit design platform 22, and a storage device 23. According to a present embodiment, at least one of the user device 21, the integrated circuit design platform 22, and the storage device 23 may be a separate device, and the user device 21, the integrated circuit design platform 22, and the storage device 23 can be connected to each other through wired or wireless communication or a wired or wireless network. According to an embodiment, at least one of the user device 21, the integrated circuit design platform 22, and the storage device 23 may be spaced apart from each other.

According to an embodiment, the user device 21 includes a processor 21a and a user interface UI 21b. The processor 21a operates the integrated circuit design platform 22 according to user input received through the user interface 21b. The integrated circuit design platform 22 is a set of computer-readable instructions for designing an integrated circuit, and includes a layout generation module 22a, a parasitic extraction module 22b, and a simulation module 22c. The storage device 23 includes a cell library database (DB) 23a and a layout DB 23b. The cell library DB 23a stores information about cells needed to generate integrated circuit layouts, and the layout DB 23b store information about layouts generated using the layout generation module 22a, specifically, physical information about the layout.

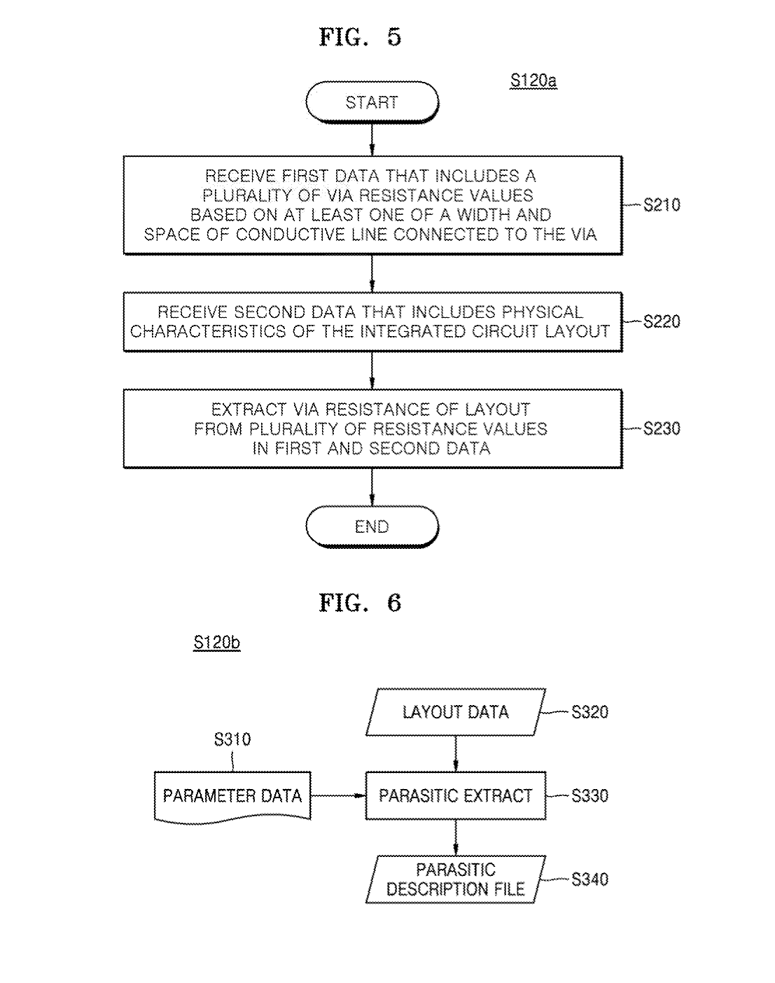

FIG. 5 is a flowchart of an integrated circuit designing method S120a according to an embodiment of the inventive concept.

Referring to FIG. 5, according to embodiments, the integrated circuit designing method S120a is directed to extracting a parasitic element from a layout, and corresponds to an embodiment of operation S120 of FIG. 1. The parasitic element includes the parasitic resistance or parasitic capacitance of a via and the parasitic resistance or parasitic capacitance of a metal layer. Hereinafter, a present embodiment will be described with reference to the extraction of a parasitic resistance of a via, hereinafter referred to as a “via resistance”. However, embodiments of the inventive concept are not limited thereto, and a method of extracting a parasitic element from a layout may incorporate a method of extracting a parasitic capacitance of a via or a parasitic resistance or a parasitic capacitance of a metal layer in a substantially similar manner.

According to embodiments, in operation S210, first data that includes a plurality of via resistance values, based on at least one of a width and a space of a conductive line connected to the via, is received. A width of a conductive line refers to the size of the conductive line in a direction perpendicular to its extension direction and is referred to as a critical dimension. A space of a conductive line refers to a distance between a conductive line connected to a via, referred to as a “real conductive line”, and an adjacent conductive line, referred to as a “dummy conductive line”. The real conductive line and the dummy conductive line are placed at the same level to form one routing layer.

According to embodiments, a conductive line refers to a predetermined pattern that is formed of a conductive material and contacts a via. According to some embodiments, a conductive line is an upper metal layer disposed on and connected to a via. According to other embodiments, a conductive line is a lower metal layer disposed under and connected to a via. According to still other embodiments, a conductive line is an active region or a gate line disposed under a via.

According to embodiments, the first data is generated in a predetermined format that includes a plurality of resistance values with respect to a via. According to some embodiments, the first data is generated in a front-end design process of an integrated circuit. According to other embodiments, the first data is stored in a standard cell library. For example, the first data can be stored in the storage device 17 of FIG. 3 or the cell library DB 23a included in the storage device 23 of FIG. 4.

According to embodiments, in operation S220, second data that includes physical characteristics of an integrated circuit layout is received. An integrated circuit layout is generated, for example, in operation S110 of FIG. 1. The physical characteristics of a layout include, for example, a width, a space, and a length of each of a plurality of patterns included in the layout. According to an embodiment, the physical characteristics of a layout include a width or a space of a conductive line. In addition, the second data may be stored in the storage device 17 of FIG. 3 or the layout DB 23b included in the storage device 23 of FIG. 4.

According to embodiments, in operation S230, a via resistance based on the layout is extracted from the plurality of resistance values in the first and second data. In detail, a resistance value that corresponds to at least one of a width value and a space value included in the first data is extracted as a via resistance. For example, the CPU 11 operates the parasitic extraction module 13b loaded in the working memory 13 to extract a via resistance.

FIG. 6 is a detailed flowchart of a parasitic extraction operation S120b according to an embodiment of the inventive concept.

Referring to FIG. 6, according to embodiments, the parasitic extraction operation S120b corresponds to an embodiment of operation S120 of FIG. 1 or to a detailed embodiment of the method illustrated in FIG. 5. In operation S310, parameter data is received. Parameter data includes a plurality of resistance values and capacitance values with respect to one via, and the plurality of resistance values and capacitance values are defined based on at least one of a width and a space of a conductive line connected to a via. According to an embodiment, parameter data is provided in a front-end design process of an integrated circuit. According to an embodiment, parameter data is received as a technology file.

In operation S320, according to embodiments, layout data is received. Layout data includes physical or geometric characteristics regarding various patterns included in a layout, and is thus referred to as physical data or geometric data. In detail, layout data includes a width value and a space value of a conductive line included in a layout. According to some embodiments, layout data is provided by a P&R tool. According to other embodiments, layout data is provided as a Design Exchange Format (DEF) file. A DEF file is a representation of an integrated circuit layout in ASICII format.

In operation S330, according to embodiments, a parasitic element is extracted. According to some embodiments, a via resistance selected from a plurality of resistance values in the parameter data, based on at least one of a width value and a space value of a conductive line in the layout data, is extracted as a parasitic element. According to other embodiments, the parameter data includes a plurality of capacitance values with respect to a via, and in the parasitic extraction operation, a via capacitance selected from the plurality of capacitance values in parameter data, based on at least one of a width value and a space value of a conductive line in the layout data, is extracted as a parasitic element.

In operation S340, according to embodiments, a parasitic description file is output. According to some embodiments, a parasitic description file includes parasitic resistances and parasitic capacitances of each of the conductive lines and vias that form one net of an integrated circuit, that is, one interconnection layout. According to other embodiments, a parasitic description file includes entire parasitic resistances and capacitances corresponding to one net of an integrated circuit. According to further embodiments, a parasitic description file is provided as a Standard Parasitic Exchange Format (SPEF) file. A SPEF file is a representation of parasitic data of a wire in an integrated circuit in ASICII format.

FIG. 7 is a detailed flowchart of a timing analysis operation S130a according to an embodiment of the inventive concept.

Referring to FIG. 7, according to embodiments, the timing analysis operation S130a corresponds to an embodiment of operation S130 of FIG. 1. In addition, besides timing analysis, the post-layout simulation of operation S130 of FIG. 1 further includes other simulation operations such as power analysis, noise analysis, or reliability analysis.

In operation S410, according to embodiments, timing data is received. According to some embodiments, timing data is provided in a front-end design process of an integrated circuit. According to other embodiments, timing data is generated while generating a standard cell library. According to further embodiments, timing data is provided as a Standard Delay Format (SDF) file.

In operation S420, according to embodiments, a parasitic description file is received. A parasitic description file is output by the parasitic extraction operation described with reference to FIG. 6. According to a present embodiment, the parasitic description file includes a via resistance selected from the plurality of resistance values, based on physical data of a layout, that is, a width value and a space value of a conductive line. Thus, a via resistance value in a parasitic description file may be close to an actual via resistance in a semiconductor device manufactured based on the layout. According to a present embodiment, the parasitic description file includes a via capacitance selected from the plurality of capacitance values, based on physical data of a layout, that is, a width value and a space value of a conductive line. Thus, a via resistance value in a parasitic description file may be close to an actual via resistance in a semiconductor device manufactured based on the layout, and a via capacitance value in a parasitic description file may be close to an actual via capacitance in a semiconductor device manufactured based on the layout.

In operation S430, according to embodiments, timing analysis is performed. In detail, whether a layout satisfies a preset timing constraint can be determined through a timing analysis. According to a present embodiment, timing analysis is performed based on a via resistance selected from the plurality of resistance values, based on a width value and a space value of a conductive line included in a layout, and thus, a value can be obtained that is close to an interconnect delay that occurs in a semiconductor device manufactured based on the layout. According to a present embodiment, timing analysis is performed based on a via capacitance selected from the plurality of capacitance values, based on a width value and a space value of a conductive line included in a layout, and thus, a value can be obtained that is close to an interconnect delay that occurs in a semiconductor device manufactured based on the layout. According to an embodiment, timing analysis is a Static Timing Analysis (STA). In operation S440, a timing report is output.

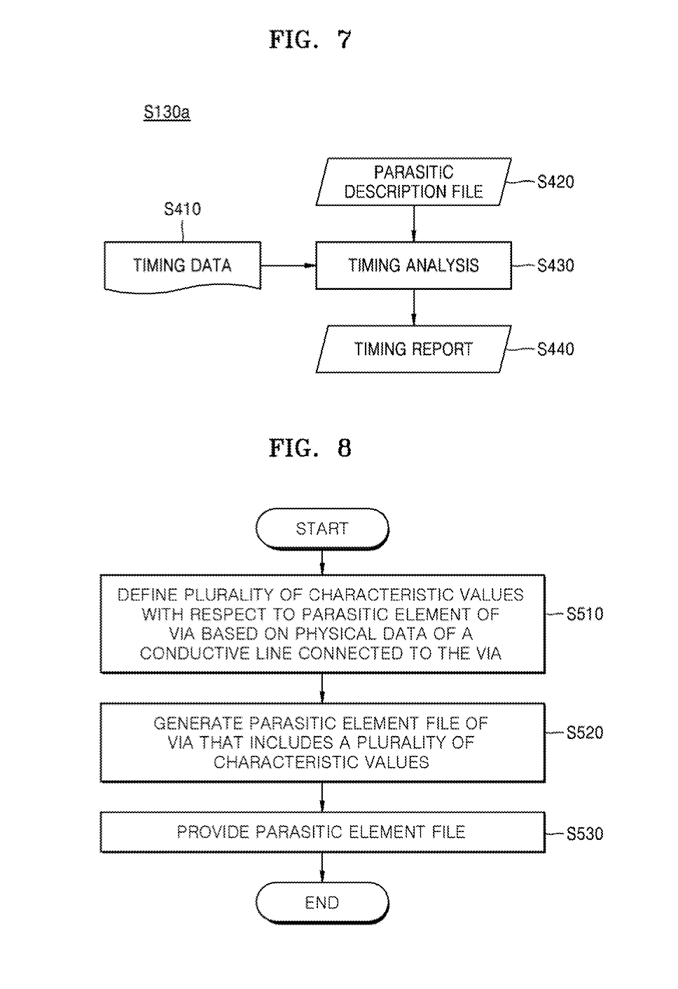

FIG. 8 is a flowchart of a method of designing an integrated circuit according to an embodiment of the inventive concept.

Referring to FIG. 8, according to embodiments, a method of designing an integrated circuit generates a parasitic element file, and can be performed, for example, prior to operation S110 of FIG. 1. Descriptions provided with reference to FIGS. 1 through 7 may apply to a present embodiment, and repeated descriptions thereof will be omitted.

In operation S510, according to embodiments, a plurality of characteristic values are defined with respect to a parasitic element of a via, based on physical data of a conductive line connected to a via included in an integrated circuit. According to some embodiments, a parasitic element of a via includes a via resistance. According to other embodiments, a parasitic element of a via includes a via capacitance.

According to some embodiments, a plurality of characteristic values are defined based on at least one of a width of an upper conductive line disposed on a via or a space between the upper conductive line and an adjacent upper conductive line. According to other embodiments, a plurality of characteristic values are defined based on at least one of a width of a lower conductive line disposed under a via or a space between the lower conductive line and an. adjacent lower conductive line. According to further embodiments, a plurality of characteristic values are defined based on at least one of a width and a space of an upper conductive line or based on at least one of a width and a space of a lower conductive line.

In operation S520, according to embodiments, a parasitic element file that includes the plurality of characteristic values is generated. According to some embodiments, a parasitic element file is generated as a plurality of files. According to other embodiments, a parasitic element file is provided as a technology file. According to further embodiments, a parasitic element file includes characteristic values of a via resistance or a via capacitance based on an upper conductive line. According to further embodiments, a parasitic element file includes characteristic values of a via resistance or a via capacitance based on a lower conductive line. According to further embodiments, a parasitic element file includes characteristic values of a via resistance or a via capacitance based on an upper conductive line and a lower conductive line.

In operation S530, according to embodiments, the parasitic element file is output. According to some embodiments, a parasitic element file is stored in a standard cell library. According to other embodiments, a parasitic element file is stored as a portion of a standard cell library, and may be stored, for example, in the cell library DB 23a (see FIG. 4). However, embodiments of the inventive concept are not limited thereto, and a parasitic element file may be stored separately from a standard cell library.

According to some embodiments, after operation S530, the method further includes an operation of generating an integrated circuit layout by referring to the standard cell library based on input data that defines an integrated circuit. According to other embodiments, after operation S530, the method further includes an operation of extracting a parasitic element of a via from a parasitic element file stored in a standard cell library based on physical characteristics of a layout.

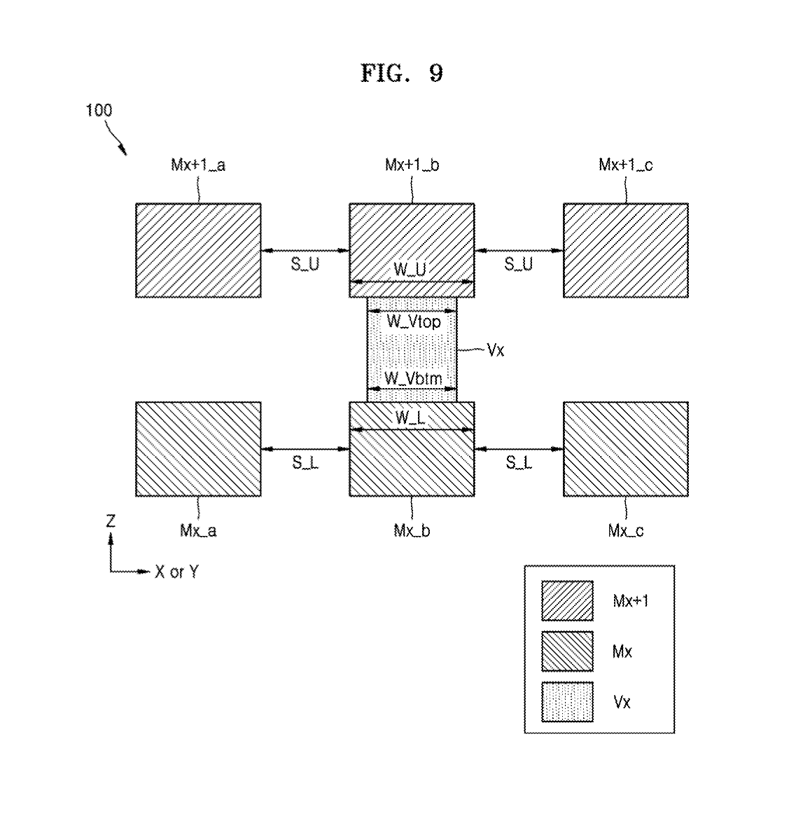

FIG. 9 illustrates a routing structure included in an integrated circuit 100 according to an embodiment of the inventive concept.

Referring to FIG. 9, according to embodiments, the integrated circuit 100 includes lower conductive lines Mx_a, Mx_b, and Mx_c and upper conductive lines Mx+1_a, Mx+1_b, and Mx+1_c. The lower conductive lines Mx_a, Mx_b, and Mx_c are referred to as lower metal patterns, and the upper conductive lines Mx+1_a, Mx+1_b, and Mx+1_c are referred to as upper metal patterns.

According to embodiments, the lower conductive lines Mx_a, Mx_b, and Mx_c are disposed on the same level as each other to form a lower metal layer Mx. The lower conductive line Mx_b is disposed under a via Vx and is electrically connected to the via Vx, and is thus referred to as a real lower conductive line. The lower conductive lines Mx_a and Mx_c on either side of the lower conductive line Mx_b are not electrically connected to the via Vx, and are thus referred to as dummy lower conductive lines, Hereinafter, a width of the lower conductive line Mx_b is denoted as W_L, and a space between the lower conductive line Mx_b and the adjacent dummy lower conductive lines Mx_a, and Mx_c is denoted as S_L.

According to embodiments, the upper conductive lines Mx+1_a, Mx+1_,b, and Mx+1_c are disposed on the same level to form an upper metal layer Mx+1. The upper conductive line Mx+1_b is disposed on the via Vx and is electrically connected to the via Vx, and accordingly, is referred to as a real upper conductive line. The upper conductive lines Mx+1_a and Mx+1_c on either side of the upper conductive line Mx+1_b are not electrically connected to the via Vx, and are thus referred to as dummy upper conductive lines. Hereinafter, a width of the upper conductive line Mx+1_b is denoted as W_U, and a space between the upper conductive line Mx+1_b and the adjacent dummy upper conductive lines Mx+1_a and Mx+1_c is denoted as

According to embodiments, a width of a top surface of the via Vx contacting the upper conductive line Mx+1_b is denoted as W_Vtop, and a width of a bottom surface of the via Vx contacting the lower conductive line Mx_b is denoted as W_Vbtm, According to an embodiment, the widths W_top and W_Vbtm can differ from each other.

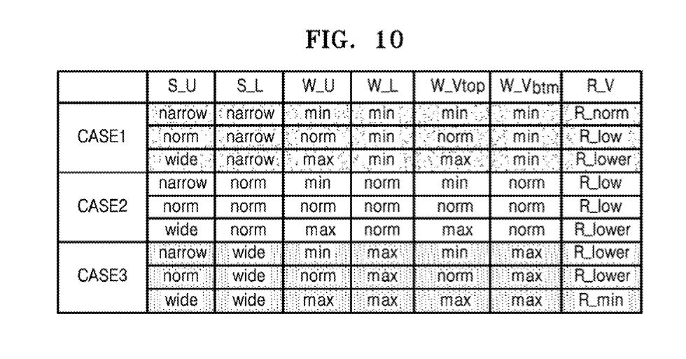

According to embodiments, when the via Vx is formed using a self-aligned via (SAV) formation process, the top surface width W_Vtop is adaptively determined based on the width of the upper conductive line Mx+1_b. In addition, when the via Vx is formed using an SAV process, the bottom surface width W_Vbtm is adaptively determined based on the width of the lower conductive line Mx_b. As described above, due to characteristics of an SAV process, critical dimensions of the via Vx, that is, the top surface width W_Vtop and the bottom surface width W_Vbtm are correlated to the critical dimensions of the upper conductive line and the lower conductive line, and accordingly, a variation in via resistance increases. This will be described in more detail below with reference to FIG. 10.

FIG. 10 is a table showing via resistances according to widths and spaces of an upper conductive line and a lower conductive line connected to a via according to an embodiment of the inventive concept.

Referring to FIG. 10, according to embodiments, a first case CASE1 shows a correlation between width W_U and space S_U of an upper conductive line and the critical dimensions and resistances of a via when width W_L of a lower conductive line has a least value. A second case CASE2 shows a correlation between width W_U and space S_U of an upper conductive line and the critical dimensions and resistances of a via when width W_L of a lower conductive line has an average value greater than the least value. A third case CASE3 shows a correlation between width W_U and space S_U of an upper conductive line and the critical dimensions and resistances of a via when width W_L of a lower conductive line has a greatest value greater than the average value. Hereinafter, the first through third cases CASE1 through. CASE3 will be described in detail.

According to embodiments, in the first case CASE1, when the space S_L and width of a lower conductive line are smallest in an SAV process, a width W_Vbtm of a bottom surface of a via also has a least value, and when a space S_U and a width W_U of an upper conductive line have a least value, a width W_top of a top surface of the via also has a least value. According to the related art, a via resistance R_V of a worst case is determined as an average resistance R_norm, and the average resistance R_norm is described as a fixed parasitic resistance regardless of the critical dimensions of a lower conductive line and an upper conductive line connected to a via. Consequently, the average resistance R_norm is extracted as a parasitic element in a parasitic extraction operation.

However, according to embodiments, in the first case CASE1, as the space S_U and the width W_U increase in size, the via width W_Vtop of the top surface of the via also increases and the via resistance R_V decreases. If a timing analysis is conducted based on the fixed, average resistance R_norm, a timing analysis result does not reflect a change in an interconnect delay caused due to the reduction in the via resistance R_V.

According to embodiments, in the second case CASE2, when the space S_L and width W_L of a lower conductive line have an average value in an SAV process, a width W_Vbtm of a bottom surface of a via also has an average value that is greater than the least value, and even if the space S_U and width W_U of an upper conductive line have the least value, a via resistance R_V is less than an average resistance R_norm. In addition, as the space S_U and the width W_U increase in size, a width W_Vtop of a top surface of the via also increases and the via resistance R_V decreases.

According to embodiments, in the third case CASE3, when space space S_L and width W_L of a lower conductive line have the greatest in an SAV process, a width W_Vbtm of a bottom surface of a via also has a greatest value that is greater than the average value, and even if the space S_U and width W_U of an upper conductive line have the least value, a via resistance R_V is less than an average resistance R_norm. In addition, as the space S_U and the width W_U increases in size, a width W_Vtop of a top surface of the via also increases and the via resistance R_V decreases.

As described above, according to embodiments, when forming a via using an SAV process, critical dimensions of the via are highly correlated to critical dimensions of the upper conductive line and critical dimensions of the lower conductive line. In detail, as the widths W_U of the upper conductive line and the W_L of the lower conductive line change, the widths of the via, that is, W_Vtop or W_Vbtm, also change, and accordingly, the via resistance R_V changes. In addition, the via resistance R_V also changes due to changes in the space S_U of the upper conductive line and the space S_L of the lower conductive line. If a fixed single average resistance R_norm is used with respect to the via resistance R_V, despite a variation in the via resistance R_V, the accuracy of a subsequently performed timing analysis may decline.

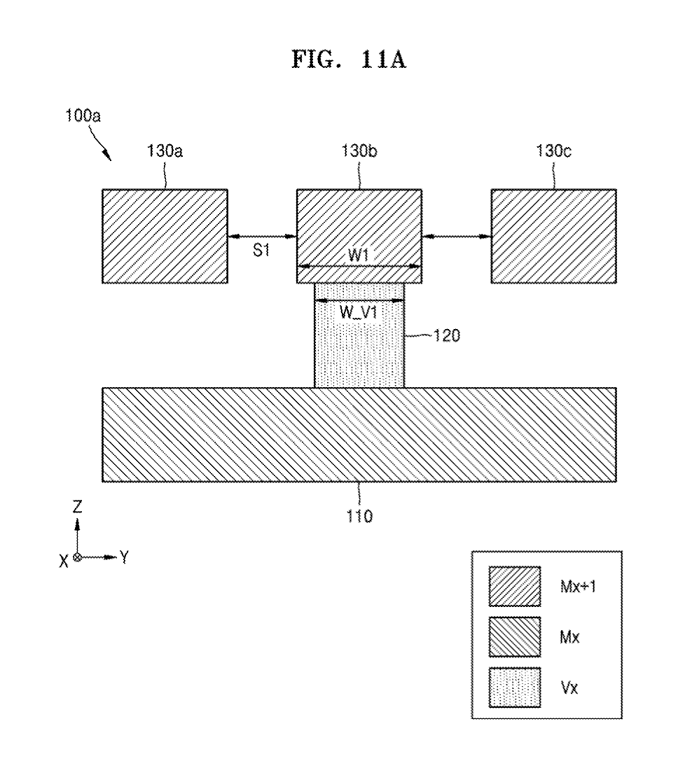

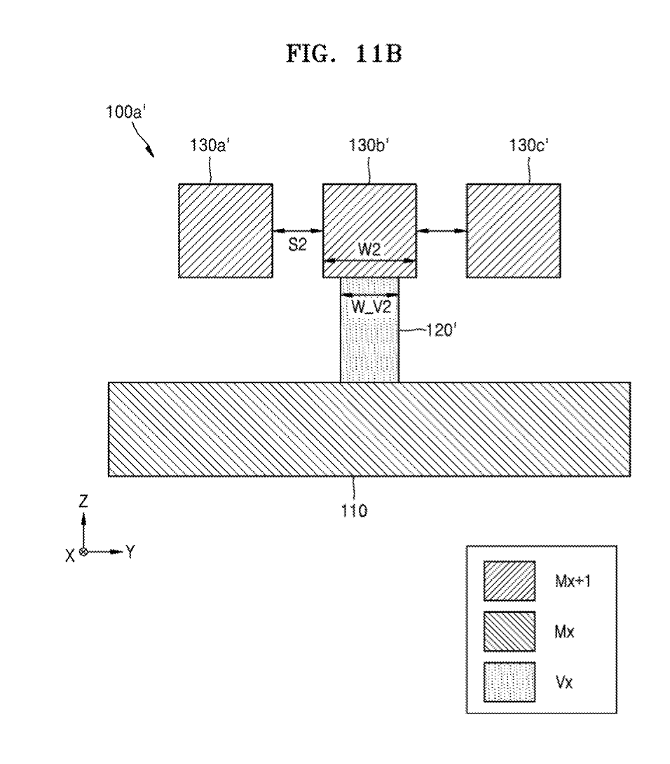

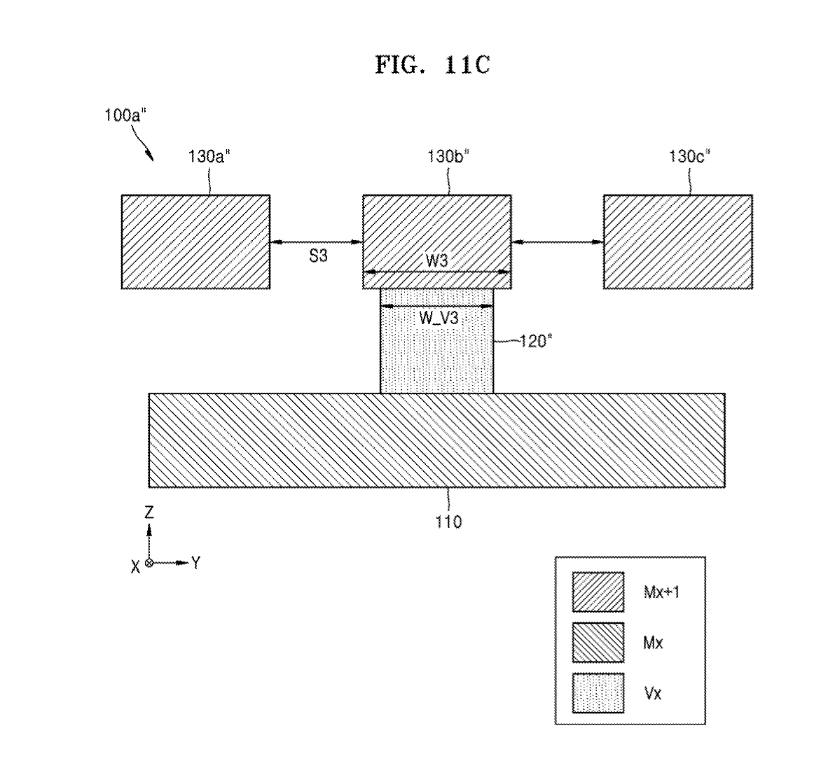

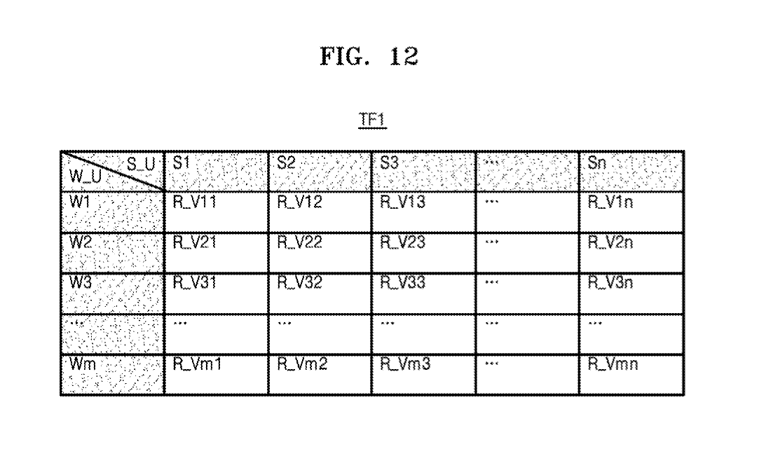

FIGS. 11A through 11C illustrate first through third layouts 100a, 100a′, and 100a″ of an integrated circuit according to an embodiment of the inventive concept. Hereinafter, an embodiment in which resistance values with respect to a via are defined based on an upper conductive line will be described with reference to FIGS. 11A through 11C and FIG. 12.

Referring to FIG. 11A, according to an embodiment, the first layout 100a of the integrated circuit includes a lower conductive line 110, a via 120, and first through third upper conductive lines 130a through 130c. The lower conductive line 110 extends in a first direction, such as a Y-direction, and the first through third upper conductive lines 130a through 130c extend in a second direction that crosses the first direction, such as an X-direction. The lower conductive line 110 corresponds to the lower metal layer Mx of FIG. 9, and the first through third upper conductive lines 130a through 130c correspond to the upper metal layer Mx+1 of FIG. 9.

According to an embodiment, the second upper conductive line 130b that directly contacts the via 120 has a width W1, and a space between the second upper conductive line 130b and the adjacent first upper conductive line 130a or a space between the second upper conductive line 130b and the adjacent third upper conductive line 130c is denoted as S1.

Referring to FIG. 11B, according to an embodiment, the second layout 100a′ of the integrated circuit includes a lower conductive line 110, a via 120′, and first through third upper conductive lines 130a′ through 130c′. The lower conductive line 110 extends in a first direction, such as a Y-direction, and the first through third upper conductive lines 130a′ through 130c′ extend in a second direction that crosses the first direction, such as an X-direction. The lower conductive line 110 corresponds to the lower metal layer Mx of FIG. 9, and the first through third upper conductive lines 130a′ through 130c′ correspond to the upper metal layer Mx+1 of FIG. 9.

According to an embodiment, the second upper conductive line 130b′ that directly contacts the via 120′ has a width W2, and a space between the second upper conductive line 130b′ and the adjacent first upper conductive line 130a′ or a space between the second upper conductive line 130b′ and the adjacent third upper conductive line 130c′ is denoted as S2. Width W2 is smaller than width W1, and space S2 is smaller than space S1. Thus, when forming an integrated circuit based on the second layout 100a′, a width W_V2 of via 120′ is smaller than a width W_V1 of via 120, and accordingly, a resistance of via 120′ is greater than a resistance of via 120.

Referring to FIG. 11C, according to an embodiment, the third layout 100a″ of the integrated circuit includes a lower conductive line 110, a via 120″, and first through third upper conductive lines 130a″ through 130c″. The lower conductive line 110 extends in a first direction, such as a Y-direction, and the first through third upper conductive lines 130a″ through 130c″ extend in a second direction that crosses the first direction, such as an X-direction. The lower conductive line 110 corresponds to the lower metal layer Mx of FIG. 9, and the first through third upper conductive lines 130a″ through 130c″ correspond to the upper metal layer Mx+1 of FIG. 9.

According to an embodiment, the second upper conductive line 130b″ that directly contacts the via 120″ has a width W3, and a space between the second upper conductive line 130b″ and the adjacent first upper conductive line 130a″ or a space between the second upper conductive line 130b″ and the adjacent third upper conductive line 130c″ is denoted as S3. Width W3 is greater than width W1, and space S3 is greater than space S1. Thus, when forming an integrated circuit based on the third layout 100a″, a width W_3 of the via 120″ is greater than a width W_V1 of via 120, and accordingly, a resistance of via 120″ is less than a resistance of via 120.

FIG. 12 illustrates a first technology file TF1 according to an embodiment of the inventive concept,

Referring to FIG. 12, according to an embodiment, the first technology file TF1 includes a plurality of resistance values R_V11 through R_Vmn with respect to a via, defined based on a width W_U and a space S_U of an upper conductive line. While m and n are illustrated as integers greater than 3 in FIG. 12, embodiments of the inventive concept are not limited thereto, and according to an embodiment, m and n are integers equal to or greater than 2. According to an embodiment, m and n are equal to each other, and in another embodiment, m and n differ from each other. According to another embodiment, m is 1, and n is an integer equal to or greater than 2. According to another embodiment, in is an integer equal to or greater than 2, and n is 1.

For example, according to embodiments, an upper conductive line corresponds to the second upper conductive lines 130b, 130b′, and 130b″ illustrated in FIGS. 11A through 11C, and a via corresponds to the vias 120, 120′, and 120″ illustrated in FIGS. 11A through 11C. W1 is a width of the second upper conductive line 130b of FIG. 11A, W2 is a width of the second upper conductive line 130b′ of FIG. 11B, and W3 is a width of the second upper conductive line 130b″ of FIG. 11C. In addition, S1 is a space adjacent to the second upper conductive line 130b of FIG. 11A, S2 is a space adjacent to the second upper conductive line 130b′ of FIG. 11B, and S3 is a space adjacent to the second upper conductive line 130b″ of FIG. 11C.

According to a present embodiment, instead of a fixed resistance value with respect to a via, a plurality of resistance values can be predefined in the first technology file TF1 based on a width W_U or a space S_U of an upper conductive line connected to a via. Accordingly, timing of an integrated circuit can be analysed in a post-layout simulation operation using a via resistance selected from the plurality of resistance values based on the width value or space value of an upper conductive line included in an actual layout, thereby increasing accuracy of an analysis result.

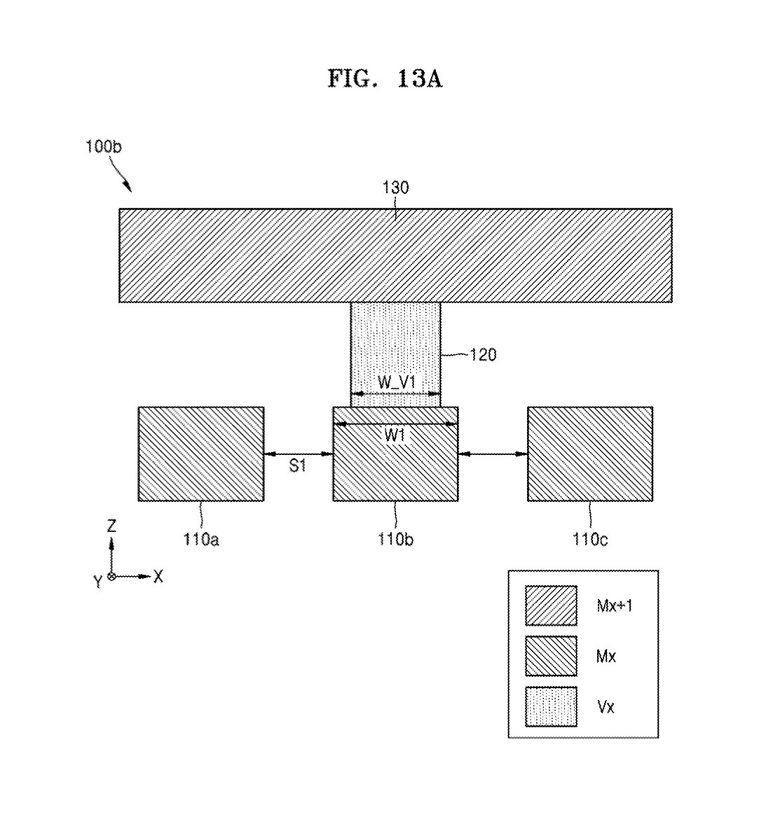

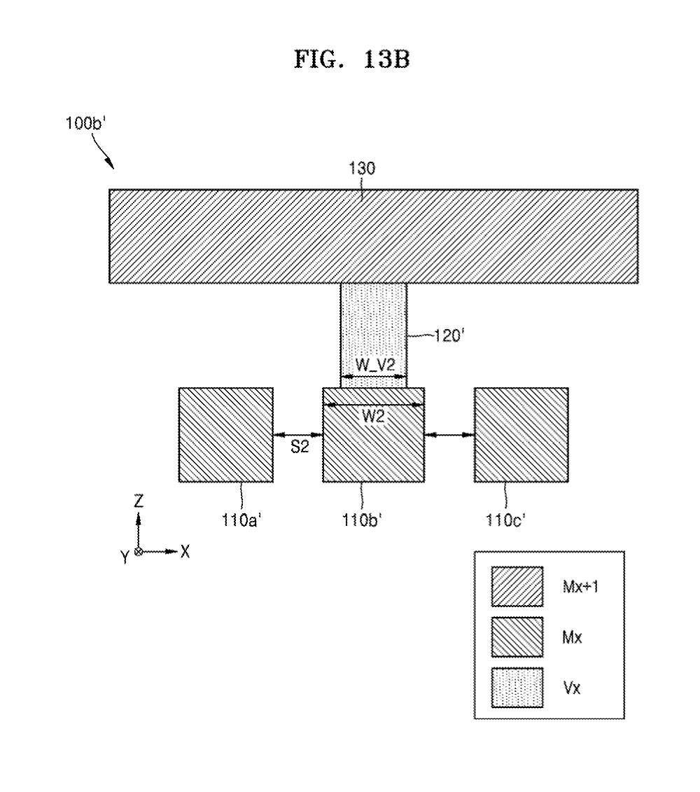

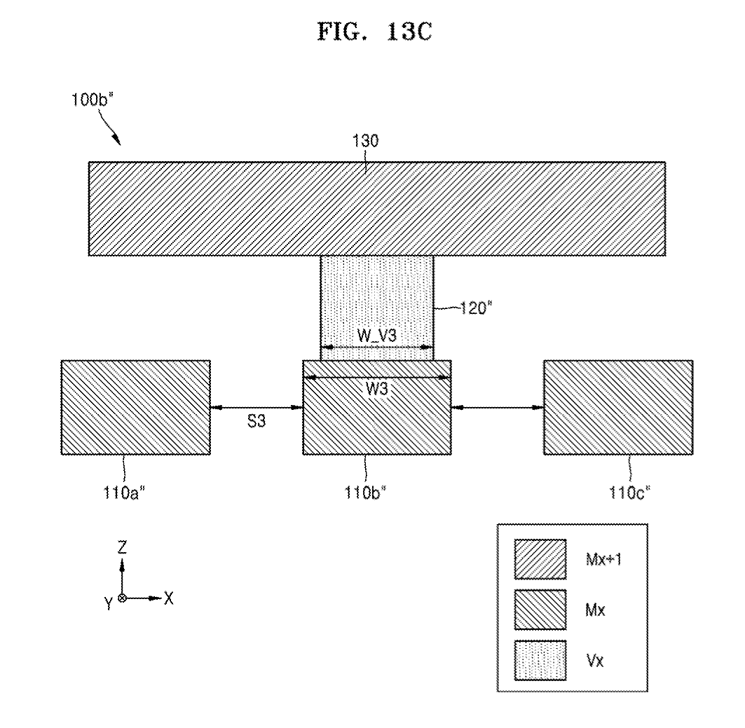

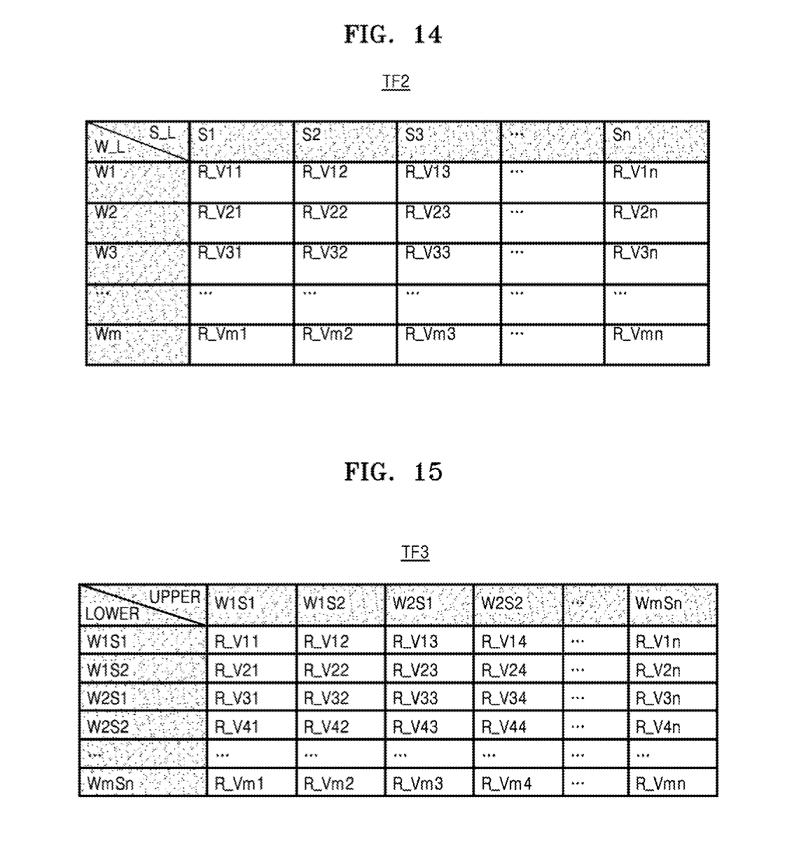

FIGS. 13A through 13C illustrate layouts 100b through 100b″ of an integrated circuit according to an embodiment of the inventive concept. Hereinafter, an embodiment, in which resistance values with respect to a via are defined according to a lower conductive line, will be described with reference to FIGS. 13A through 13C and 14.

Referring to FIG. 13A, according to an embodiment, the first layout 100b of the integrated circuit includes first through third lower conductive lines 110a through 110c, a via 120, and an upper conductive line 130. The first through third lower conductive lines 110a through 110c extend in a first direction, such as a Y-direction, and the upper conductive line 130 extends in a second direction that crosses the first direction such as an X-direction. The first through third lower conductive lines 110a through 110c correspond to the lower metal layer Mx of FIG. 9, and the upper conductive line 130 corresponds to the upper metal layer Mx+1 of FIG. 9.

According to an embodiment, the second lower conductive line 110b that directly contacts the via 120 has a width W1, and a space between the second lower conductive line 110b and the adjacent first lower conductive line 110a or a space between the second lower conductive line 110b and the adjacent third lower conductive line 110c is denoted as S1.

Referring to FIG. 13B, according to an embodiment, the second layout 100b′ of the integrated circuit includes first through third lower conductive line 110a′ through 110c′, a via 120′, and an upper conductive line 130. The first through third lower conductive lines 110a′ through 110c′ extend in a first direction, such as a Y-direction, and the upper conductive line 130 extends in a second direction that crosses the first direction, such as an X-direction. The first through third lower conductive line 110a′ through 110c′ correspond to the lower metal layer Mx of FIG. 9, and the upper conductive line 130 corresponds to the upper metal layer Mx+1 of FIG. 9.

According to an embodiment, the second lower conductive line 110b′ that directly contacts the via 120′ has a width W2, and a space between the second lower conductive line 110b′ and the adjacent first lower conductive line 110a′ or a space between the second lower conductive line 110b′ and the adjacent third lower conductive line. 110c′ is denoted as S2. Width W2 is smaller than width W1, and space S2 is smaller than space S1. Thus, when forming an integrated circuit based on the second layout 100b′, a width W_V2 of via 120′ is smaller than a width W_V1 of via 120, and accordingly, a resistance of via 120′ is greater than a resistance of via 120.

Referring to FIG. 13C, according to an embodiment, the third layout 100b″ of the integrated circuit includes first through third lower conductive line 110a″ through 110c″, a via 120″, and an upper conductive line 130. The first through third lower conductive lines 110a″ through 110c″ extend in a first direction, such as a Y-direction, and the upper conductive line 130 extends in a second direction that crosses the first direction, such as an X-direction. The first through third lower conductive line 110a″ through 110c″ correspond to the lower metal layer Mx of FIG. 9, and the upper conductive line 130 corresponds to the upper metal layer Mx+1 of FIG. 9.

According to an embodiment, the second lower conductive line 110b″ that directly contacts the via 120″ has a width W3, and a space between the second lower conductive line 110b″ and the adjacent first lower conductive line 110a″ or a space between the second lower conductive line 110b″ and the adjacent third lower conductive line 110c″ is denoted as S3. Width W3 is greater than width W1, and space S3 is greater than space S1. Thus, when forming an integrated circuit based on the third layout 100b″, a width W_V3 of via 120″ is greater than a width W_V1 of via 120, and accordingly, a resistance of via 120″ is less than a resistance of via 120.

FIG. 14 illustrates a second technology file TF2 according to an embodiment of the inventive concept.

Referring to FIG. 14, according to an embodiment, the second technology file TF2 includes a plurality of resistance values R_V11 through R_Vmn with respect to a via, defined based on a width W_L and a space S_L of a lower conductive line. While m and n are illustrated as integers greater than 3 in FIG. 14, embodiments of the inventive concept are not limited thereto, and according to an embodiment, m and n are integers equal to or greater than 2. According to another embodiment, m and n are equal to each other, and in another embodiment, m and n differ from each other. According to another embodiment, m is 1, and n is an integer equal to or greater than 2. According to another embodiment, m is an integer equal to or greater than 2, and n is 1.

For example, according to an embodiment, a lower conductive line corresponds to the second lower conductive lines 110b, 110b′, and 110b″ illustrated in FIGS. 13A through 13C, and a via corresponds to the vias 120, 120′, and 120″ illustrated in FIGS. 13A through 13C. W1 is a width of the second lower conductive line 110b of FIG. 13A, W2 is a width of the second lower conductive line 110b′ of FIG. 13B, and W3 is a width of the second lower conductive line 110b″ of FIG. 13C. In addition, S1 is a space adjacent to the second lower conductive line 110b of FIG. 13A, S2 is a space adjacent to the second lower conductive line 110b′ of FIGS. 13B, and S3 is a space adjacent to the second lower conductive line 110b″ of FIG. 13C.

According to a present embodiment, instead of a fixed resistance value with respect to a via, a plurality of resistance values can be predefined in the second technology file TF2 based on a width W_L or a space S_L of a lower conductive line connected to a via. Accordingly, timing of an integrated circuit can be analysed in a post-layout simulation operation using a via resistance selected from the plurality of resistance values based on a width value or a space value of a lower conductive line included in an actual layout, thereby increasing accuracy of an analysis result.

FIG. 15 illustrates a third technology file TF3 according to an embodiment of the inventive concept.

Referring to FIG. 15, the third technology file TF3 includes a plurality of resistance values R_V11 through R_Vmn with respect to a via, defined based on a width and a space of a lower conductive line LOWER and a width and a space of an upper conductive line UPPER. While m and n are illustrated as integers greater than 3 in FIG. 15, embodiments of the inventive concept are not limited thereto, and according to an embodiment, m and n are integers equal to or greater than 2. According to another embodiment, m and n are equal to each other, and in another embodiment, m and n differ from each other. According to another embodiment, m is 1, and n is an integer equal to or greater than 2. According to another embodiment, m is an integer equal to or greater than 2, and n is 1.

For example, according to an embodiment, the lower conductive line LOWER corresponds to the second lower conductive lines 110b, 110b′, and 110b″ illustrated in FIGS. 13A through 13C, and a via corresponds to the vias 120, 120′, and 120″ illustrated in FIGS. 13A through 13C. With regard to the lower conductive line LOWER, W1 is a width of the second lower conductive line 110b of FIG. 13A, W2 is a width of the second lower conductive line 110b′ of FIG. 13B, and W3 is a width of the second lower conductive line 110b″ of FIG. 13C. In addition, with regard to the lower conductive line LOWER, S1 is a space adjacent to the second lower conductive line 110b of FIG. 13A, S2 is a space adjacent to the second lower conductive line 110b′ of FIG. 13B, and S3 is a space adjacent to the second lower conductive line 110b″ of FIG. 13C.

In addition, according to an embodiment, the upper conductive line UPPER corresponds to the second upper conductive lines 130b, 130b′, and 130b″ illustrated in FIGS. 11A through 11C, and a via corresponds to the vias 120, 120′, and 120″ illustrated in FIGS. 11A through 11C. With regard to the upper conductive line UPPER, W1 is a width of the second upper conductive line 130b of FIG. 11A, W2 is a width of the second upper conductive line 130b′ of FIG. 11B, and W3 is a width of the second upper conductive line 130b″ of FIG. 11C. In addition, with regard to the upper conductive line UPPER, S1 is a space adjacent to the second upper conductive line 130b of FIG. 11A, S2 is a space adjacent to the second upper conductive line 130b′ of FIG. 11B, and S3 is a space adjacent to the second upper conductive line 130b″ of FIG. 11C.

According to a present embodiment, a plurality of resistance values can be defined by considering both the width and space of the lower conductive line LOWER disposed under the via and both the width and space of the upper conductive line UPPER disposed on the via. According to a present embodiment, instead of a fixed resistance value with respect to a via, a plurality of resistance values can be predefined in the third technology file TF3 based on a width or a space of an upper conductive line connected to a via and based on a width or a space of a lower conductive line connected to a via. Accordingly, timing of an integrated circuit can be analysed in a post-layout simulation operation using a via resistance selected from the plurality of resistance values based on a width value or a space value of an upper conductive line in an actual layout and a width value or a space value of a lower conductive line in an actual layout, thereby increasing accuracy of an analysis result.

According to a present embodiment, as described above with reference to FIGS. 11A through 15, instead of a fixed characteristic value associated with elements in an integrated circuit, such as a pattern formed on a routing layer, a via or a transistor, a plurality of characteristic values can be predefined in a technology file. Accordingly, characteristic values may be extracted from the technology file based on physical data of a layout in a parasitic extraction operation, and timing of an integrated circuit can be analysed based on the extracted characteristic values, thereby increasing accuracy of an analysis result.

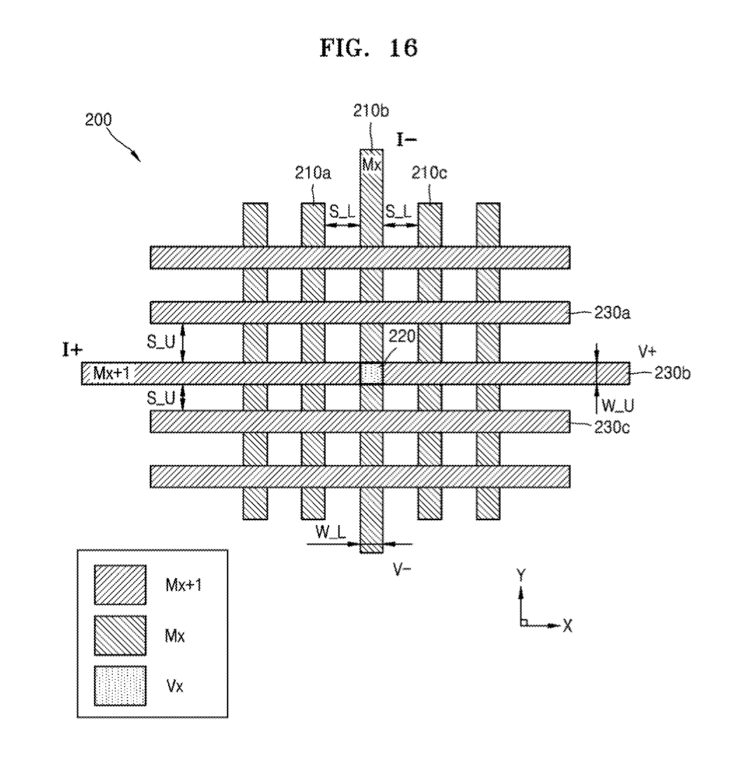

FIG. 16 illustrates a device under test (DUT) 200 used in a test operation according to an embodiment of the inventive concept.

Referring to FIG. 16, according to an embodiment, one effective measure to optimize a process or establish a design rule in a semiconductor device is process simulation. One method of verifying process simulation in hardware manner measures electrical characteristics using a Test Elements Group (TEG). In detail, a TEG is manufactured on a wafer, and electrical characteristics are measured from the wafer having the TEG to thereby extract model parameters. The model parameters are physical or structural parameters and may include, for example, a channel length, a device width, a doping profile, an oxide layer thickness, an oxide layer permittivity, and a channel length modulation index. The extracted model parameters are input to a simulator, and the behaviour of a designed circuit is verified using the simulator, and a layout is drafted to comply with the design rule.

According to a present embodiment, a model parameter includes a via resistance, and the via resistance is extracted by measuring electrical characteristics from a wafer having a TEG, using a method such as a Kelvin method. In detail, the DUT 200 may include lower conductive lines 210a through 210c extending in a first direction, such as a Y-direction, and upper conductive lines 230a through 230c extending in a second direction that crosses the first direction, such as an X-direction, and further includes a via 220 that electrically connects the lower conductive line 210b and the upper conductive line 230b.

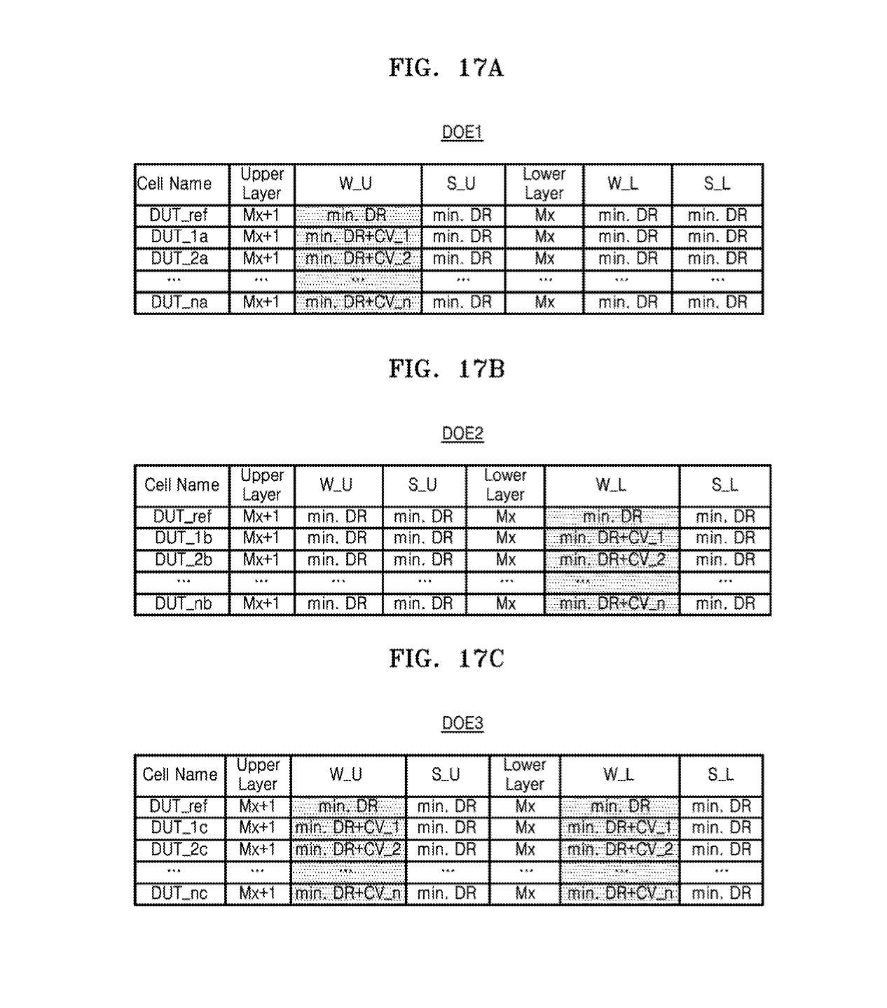

FIGS. 17A through 17C illustrate first design of experiments (DOE) DOE1, DOE2, and DOE3 used in a test operation according to an embodiment of the inventive concept.

Referring to FIG. 17A, according to the first DOE DOE1, a width W_L and a space S_L of a lower metal layer Mx are specified based on a minimum design rule, and a width W_U of an upper metal layer Mx+1 can vary. To prevent the influence of a Catastropic OPC (CATOPC), a space S_U of the upper metal layer Mx+1 is specified based on a minimum design rule. By performing a test operation based on the first DOE DOE1, for example, the first technology file TF1 illustrated in FIG. 12 can be verified.

Referring to FIG. 17B, according to the second DOE DOE2, a width W_U and a space S_U of an upper metal layer Mx+1 are specified based on a minimum design rule, and a width W_L of a lower metal layer Mx can vary. To prevent the influence of a CATOPC, a space S_L of the lower metal layer Mx is specified based on a minimum design rule. By performing a test operation based on the second DOE DOE2, for example, the second technology file TF2 illustrated in FIG. 14 can be verified.

Referring to FIG. 17C, according to the third DOE DOE3, a space S_U of an upper metal layer Mx+1 and a space S_L of a lower metal layer Mx are specified based on a minimum design rule, and a width W_U of the upper metal layer Mx+1 and a width W_L of the lower metal layer Mx can vary. By performing a test operation based on the third DOE DOE3, for example, the third technology file. TF3 illustrated in FIG. 15 can be verified.

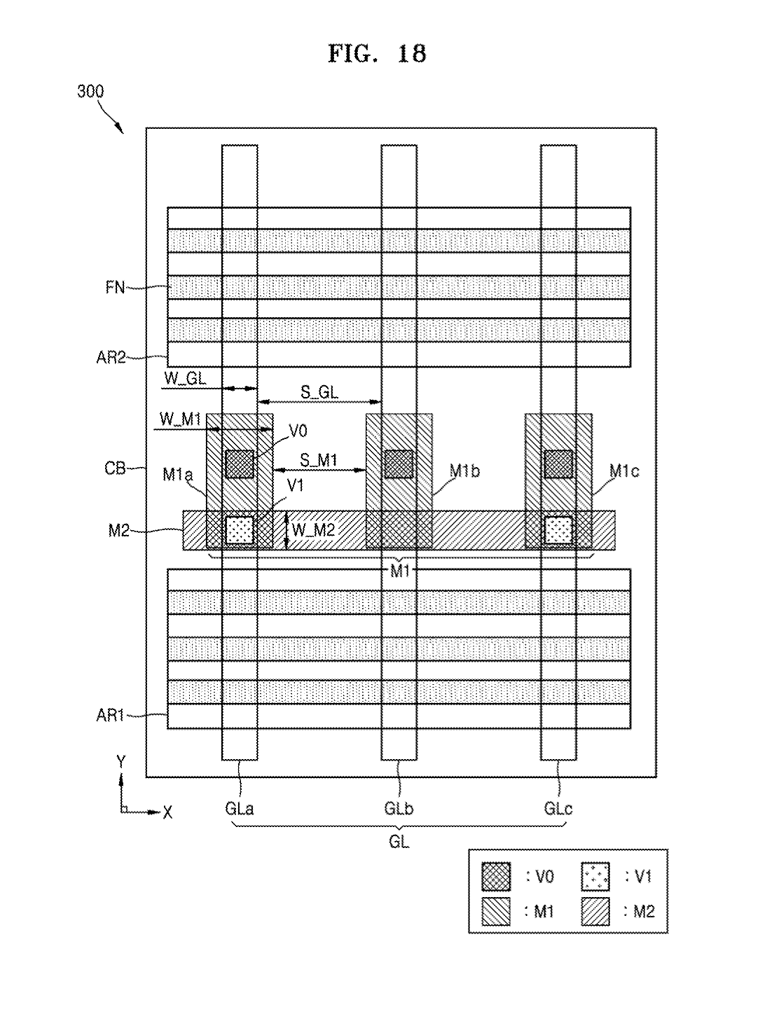

FIG. 18 is a layout of a standard cell 300 included in an integrated circuit according to an embodiment of the inventive concept.

Referring to FIG. 18, according to an embodiment, the standard cell 300 is defined by a cell boundary CB, and includes a plurality of fins FN, first and second active regions AR1 and AR2, a plurality of gate lines GL, and a plurality of first metal lines M1 and a second metal line M2. The cell boundary CB is an outline that defines the standard cell 300, and a P&R tool recognizes the standard cell 300 using the cell boundary CB. The cell boundary CB includes four boundary lines.

According to an embodiment, the plurality of fins FN extend in a second direction, such as an X-direction, and are disposed parallel to one another in a first direction perpendicular to the second direction, such as a Y-direction. The first active region AR1 and the second active region AR2 are disposed parallel to each other and have different conductivity types. In detail, according to a present embodiment, three fins FN are disposed in each of the first and second active regions AR1 and AR2. However, embodiments of the inventive concept are not limited thereto, and the number of fins FN to be disposed in each of the first and second active regions AR1 and AR2 can vary in other embodiments.

According to an embodiment, the plurality of fins FN disposed in the first and second active regions AR1 and AR2 can be referred to as active fins. While only active fins are illustrated in FIG. 18, embodiments of the inventive concept are not limited thereto, and the standard cell 300 can further include dummy fins disposed between the cell boundary CB and the first active region AR1, between the first and second active regions AR1 and AR2, or between the second active region AR2 and the cell boundary CB.

According to an embodiment, the plurality of gate lines GL extends in the first direction, such as the Y-direction, and are disposed parallel to one another in the second direction, such as the X-direction. The gate lines GL are formed of an electrically conductive material and may include, for example, polysilicon, a metal, or a metal alloy. While the standard cell 300 illustrated in FIG. 18 includes three gate lines GL, embodiments of the inventive concept are not limited thereto, and in other embodiments, the standard cell 300 can include four or more gate lines GL extending in the second direction and arranged parallel to one another in the first direction.

According to an embodiment, the plurality of first metal lines M1 form one layer, such as the lower conductive line Mx of FIG. 9, disposed above the plurality of gate lines GL. The first metal lines M1 are formed of an electrically conductive material, and may include, for example, polysilicon, a metal, or a metal alloy. The first metal lines M1 extend in the first direction, such as the Y-direction, and are disposed parallel to each other in the second direction, such as the X-direction. However, embodiments of the inventive concept are not limited thereto, and in other embodiments, the first metal lines M1 have an L-shape in which a portion of some of the first metal lines M1 extends in the first direction, and the other portion thereof extends in the second direction. In addition, while the standard cell 300 includes three first metal lines M1 in FIG. 18, embodiments of the inventive concept are not limited thereto, and in other embodiments, the standard cell 300 includes four or more first metal lines M1.

According to an embodiment, first vias V0 are respectively disposed on a plurality of gate lines GLa, GLb, and GLc to electrically connect the plurality of gate lines GLa, GLb, and GLc to a plurality of first metal lines M1a, M1b, and M1c. The first vias V0 are formed of an electrically conductive material, and may include, for example, polysilicon, a metal, or a metal alloy. A via resistance of the first via V0 varies based on physical characteristics of the gate line contacting the first via V0 under the first via V0, such as gate line GLa, and the first metal line contacting the first via V0 on the first via V0, such as the first metal line M1a.

According to a present embodiment, while designing an integrated circuit, parameter data of a plurality of resistance values with respect to the first via V0, that is, a technology file, are provided. According to an embodiment, the technology file includes a plurality of resistance values defined based on at least one of a width W_GL of the gate line GLa under the first via V0 and a space S_GL between the gate line GLa and an adjacent gate line GLb. According to another embodiment, the technology file includes a plurality of resistance values defined based on at least one of a width of the first metal line M1a on the first via V0 and a space S_M1 between the first metal line M1a and an adjacent first metal line M1b. According to another embodiment, the technology file includes a plurality of resistance values defined based on at least one of the width W_GL of the gate line GLa under the first via V0 and the space S_GL adjacent to the gate line GLa, and based on at least one of the width W_M1 of the first metal line M1a and the space S_M1 adjacent to the first metal line M1a.

According to an embodiment, the second metal line M2 forms one layer, such as the upper metal layer Mx+1 of FIG. 9, disposed on the plurality of first metal lines M1. The second metal line M2 is formed of an electrically conductive material, and may include, for example, polysilicon, a metal, or a metal alloy. The second metal line M2 extends in the second direction, such as the X-direction. However, embodiments of the inventive concept are not limited thereto, and in some embodiments, the second metal line M2 has an L-shape in which a portion of the second metal line M2 extends in the second direction, and the other portion thereof extends in the first direction. In addition, while the standard cell 300 includes one second metal line M2 in FIG. 18, embodiments of the inventive concept are not limited thereto, and in other embodiments, the standard cell 300 includes two or more second metal lines M2.

According to an embodiment, second vias V1 are disposed on the plurality of first metal lines M1a and M1c to electrically connect the plurality of first metal lines M1a and M1c to the second metal line M2. The second vias V1 are formed of an electrically conductive material, and may include, for example, polysilicon, a metal, or a metal alloy. A via resistance of the second vias V1 varies based on physical characteristics of the first metal line contacting the vias under the vias, such as the first metal line M1a, and the second metal line contacting the via on the vias, such as the second metal line M2.

According to a present embodiment, while designing an integrated circuit, parameter data defining a plurality of resistance values with respect to the second via V1, that is, a technology file, is provided. According to an embodiment, the technology file includes a plurality of resistance values defined based on at least one of a width W_M1 of the first metal line M1a under the second via V1 and a space S_M1 between the first metal line M1a and an adjacent first metal line M1b. According to another embodiment, the technology the includes a plurality of resistance values defined based on at least one of a width W_M2 of the second metal line M2 disposed on the second via V1. According to another embodiment, the technology file includes a plurality of resistance values defined based on at least one of the width W_M1 of the first metal line M1a and the space S_M1 adjacent to the first metal line M1a, and based on the width W_M2 of the second metal line M2.

As described above with reference to FIGS. 1 through 18, according to embodiments of the inventive concept, a via resistance can be extracted from the plurality of resistance values based on physical characteristics of a layout. To verify behavior of an embodiment of the inventive concept, a simulation is performed using a ring oscillator on an interconnect model, which reflects changes in via resistance due to an SAV process. Simulations have shown that, as compared to a simulation result from an interconnect model with respect to a fixed via resistance of the related art, an operating speed according to embodiments of the inventive concept was greater.

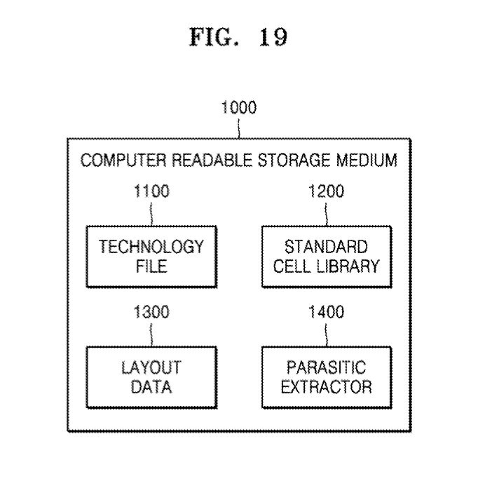

FIG. 19 is a block diagram illustrating a storage medium 1000 according to an embodiment of the inventive concept.

Referring to FIG. 19, according to an embodiment, the storage medium 1000 stores a technology file 1100, a standard cell library 1200, layout data 1300, and a parasitic extractor 1400. The storage medium 1000 is a computer-readable storage medium and includes a predetermined computer-readable storage medium that is used to supply instructions and/or data to a computer. For example, the computer-readable storage medium 1000 may include a magnetic or optical medium such as a disk, a tape, a CD-ROM, a DVD-ROM, a CD-R, CD-RW, a DVD-R, or a DVD-RW, a volatile or non-volatile memory such as a RAM, ROM, or a flash memory, or a non-volatile memory that is accessible via a Universal Serial Bus (USB) interface, or a microelectromechanical system (MEMS). The computer-readable storage medium can be coupled to a computer by being inserted into a computer or integrated into a computer, or via a communication medium such as a network and/or a wireless link.

According to an embodiment, the technology file 1100 describes electrical characteristics of a semiconductor process, and includes parameter data regarding parasitic elements such as a parasitic resistance or a parasitic capacitance with respect to metal layers and vias included in a routing structure of an integrated circuit. According to some embodiments, the technology file 1100 includes parameter data such as a plurality of resistance values with respect to a via, defined based on physical characteristics of an upper conductive line and/or a lower conductive line connected to the via. According to some embodiments, the technology file 1100 includes parameter data such as a plurality of capacitance values with respect to a via, defined based on physical characteristics of an upper conductive line and/or a lower conductive line connected to the via.

According to an embodiment, the standard cell library 1200 includes information about a standard cell unit of an integrated circuit. According to some embodiments, information about standard cells includes layout information needed to generate a layout. According to some embodiments, information about standard cells includes timing information needed to verify or simulate a layout. According to some embodiments, the technology file 1100 is stored as a portion of the standard cell library 1200.

According to an embodiment, the layout data 1300 includes physical characteristics of a layout generated through a P&R operation. The layout data 1300 includes a width value and a space value of an upper conductive line and/or a lower conductive line connected to a via in the layout. The parasitic extractor 1400 includes a plurality of instructions used to extract a parasitic element from the layout.

In some embodiments, the storage medium 1000 further stores a P&R program, and the P&R program include a plurality of instructions to generate an integrated circuit layout using a standard cell library. In some embodiments, the storage medium 1000 further stores an analysis program, and the analysis program includes a plurality of instructions that analyze an integrated circuit based on input data that defines the integrated circuit. In some embodiments, the storage medium 1000 further stores a data structure, and the data structure includes storage space for extracting particular information from the standard cell library 1200, or managing data generated while analyzing characteristics of an integrated circuit via an analysis program.

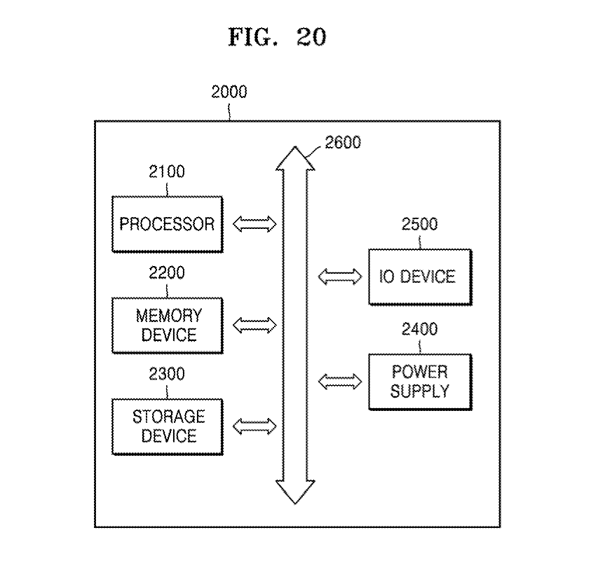

FIG. 20 is a block diagram of a computing system 2000 according to an embodiment of the inventive concept.

Referring to FIG. 20, according to an embodiment, the computing system 2000 include a processor 2100, a memory device 2200, a storage device 2300, a power supply 2400, and an input/output device 2500. In addition, the computing system 2000 may further include ports through which communication with a video card, a sound card, a memory card, a USB device or other electronic devices can be performed.

As described above, the processor 2100, the memory device 2200, the storage device 2300, the power supply 2400, and/or the input/output device 2500 included in the computing system 2000 may include an integrated circuit generated using a method of designing an integrated circuit according to embodiments of the inventive concept. According to an embodiment, at least one of the semiconductor devices included in the processor 2100, the memory device 2200, the storage device 2300, the power supply 2400, and the input/output device 2500 is formed using a method of designing an integrated circuit according to embodiments of the inventive concept.

According to an embodiment, the processor 2100 performs predetermined calculations or tasks. In detail, the processor 2100 can execute instructions that implement at least one of the methods of embodiments of the inventive concept. According to an embodiment, the processor 2100 executes a plurality of instructions to generate an integrated circuit layout. According to an embodiment, the processor 2100 executes a plurality of instructions to extract a parasitic element from a technology file that stores a plurality of characteristic values based on physical characteristics of a layout. According to an embodiment, the processor 2100 executes a plurality of instructions to simulate a parasitic element. For example, operations S110 through S130 of FIG. 1, operations S210 through S230 of FIG. 5, operations S310 through S340 of FIG. 6, operations S410 through S440 of FIG. 7, and operations S310 through S530 of FIG. 8 can be performed using the processor 2100.

According to an embodiment, the processor 2100 may be a micro-processor or a central processing unit (CPU), The processor 2100 communicates with the memory device 2200, the storage device 2300, and the input/output device 2500 via a bus 2600 such as an address bus, a control bus, and a data bus. According to an embodiment, the processor 2100 is also connected to an extension bus such as a peripheral component interconnect (PCI) bus,

According to an embodiment, the memory device 2200 stores data needed to operate the computer system 2000. For example, the memory device 2200 may be configured as a DRAM, a mobile DRAM, an SRAM, a PRAM, an FRAM, an RRAM and or an MRAM. The storage device 2300 may include a solid state drive, a hard disk drive, a CD-ROM, etc.

According to a present embodiment, the memory device 2200 stores a P&R program, a standard cell library, an analysis program, a data structure, a parasitic extraction program, a simulation program, a design rule, etc. The processor 2100 execute instructions for designing an integrated circuit according to a present embodiment using the P&R program, the standard cell library, the analysis program, the data structure, the parasitic extraction program, the simulation program, the design rule, etc., stored in the memory device 2200. Thus, the computer system 2000 can automatically design an integrated circuit using the processor 2100, that is, can design an integrated circuit layout.

According to an embodiment, the input/output device 2500 includes an input unit such as a keyboard, a keypad, or a mouse, and an output unit such as a printer or a display. The power supply 2400 supplies an operating voltage needed to operate the computing system 2000.

An integrated circuit and a semiconductor device according to an integrated circuit of embodiments of the inventive concept may be housed in any of a variety of different package types. For example, at least some elements of the integrated circuit may be may be housed using a package such as a Package on Package (PoP), a Ball grid array (BGA), a Chip Scale Package (CSP), a Plastic Leaded Chip Carrier (PLCC), a Plastic Dual In-Line Package (PDIP), a Die in Waffle Pack, a Die in Wafer Form, a Chip On Board (COB), a Ceramic Dual In-Line Package (CERDIP), a Plastic Metric Quad Hat Pack (MQFP), a Thin Quad Flat Pack (TQFP), a Small Outline Integrated Circuit (SOIC), a Shrink Small Outline Package (SSOP), a Thin Small Outline Package (TSOP), a System in Package (SIP), a Multi-Chip Package (MCP), a Wafer level Fabricated Package (WFP), a Wafer-Level Processed Stack Package (WSP), etc.

While embodiments of the inventive concept have been particularly shown and described with reference to exemplary embodiments thereof, it will be understood that various changes in form and details may be made therein without departing from the spirit and scope of the following claims.

What is claimed is:

1. A computer-implemented method of designing an integrated circuit, the method comprising:
receiving first data that includes a plurality of resistance values of a via in the integrated circuit, wherein each of the plurality of resistance values is defined based on at least one of a width of a conductive line connected to the via and a space between the conductive line and an adjacent conductive line;
receiving second data that includes physical characteristics of a layout of the integrated circuit; and
extracting, by a processor, a via resistance of the layout from the plurality of resistance values based on the first and second data.

2. The method of claim 1, wherein receiving the first data comprises receiving the plurality of resistance values wherein each of the plurality of resistance values is defined based on at least one of a width of an upper conductive line disposed on the via or a width of a space between the upper conductive line and an adjacent upper conductive line.

3. The method of claim 1, wherein receiving the first data comprises receiving the plurality of resistance values wherein each of the plurality of resistance values is defined based on at least one of a width of a lower conductive line disposed under the via and or a width of a space between the lower conductive line and an adjacent lower conductive line.

4. The method of claim 1, wherein receiving the first data comprises receiving the plurality of resistance values wherein each of the plurality of resistance values is defined based on at least one of a first width of an upper conductive line disposed on the via or a first space between the upper conductive line and an adjacent upper conductive line, and based on at least one of a second width of a lower conductive line disposed under the via or a second space between the lower conductive line and an adjacent lower conductive line.

5. The method of claim 1, further comprising, prior to receiving the second data, generating the layout by performing a placement and routing operation based on input data that defines the integrated circuit.

6. The method of claim 1, wherein receiving the second data comprises receiving the physical characteristics, said physical characteristics including at least one of a width value of the conductive line in the layout or and a space value of a space adjacent to the conductive line.

7. The method of claim 6, wherein extracting the via resistance comprises extracting from the plurality of resistance values, as the via resistance, a resistance value that corresponds to at least one of the width value and the space value.

8. The method of claim 1, further comprising, after extracting the via resistance, performing a post-layout simulation on the layout based on the via resistance.

9. The method of claim 8, wherein performing the post-layout simulation comprises performing a timing analysis on the integrated circuit based on the via resistance.

10. The method of claim 8, further comprising, after performing the post-layout simulation, modifying the layout based on a result of the post-layout simulation.

11. The method of claim 10, further comprising, after performing the post-layout simulation:
manufacturing a mask based on the layout or a modified layout; and
forming the integrated circuit on a wafer using the mask.

12. A computer-implemented method of designing an integrated circuit, the method comprising:
defining, by a processor, a plurality of characteristic values with respect to a parasitic element of a via based on physical characteristics of a conductive line connected to the via in the integrated circuit;
generating a parasitic element file of the via, wherein the parasitic element file includes the plurality of characteristic values; and
outputting the parasitic element file.

13. The method of claim 12, wherein the parasitic element of the via comprises a via resistance, and
defining the plurality of characteristic values comprises defining, a plurality of resistance values of the via based on at least one of a width of the conductive line and a space between the conductive line and an adjacent conductive line.

14. The method of claim 12, further comprising at least one of:
generating a layout of the integrated circuit by referring to a standard cell library based on input data that defines the integrated circuit; and
extracting the parasitic element of the via from the parasitic element file based on physical characteristics of the layout.

15. The method of claim 12, wherein defining the plurality of characteristic values comprises at least one of:
defining the plurality of characteristic values based on at least one of a first width of an upper conductive line disposed on the via or a first space between the upper conductive line and an adjacent upper conductive line;
defining the plurality of characteristic values based on at least one of a second width of a. lower conductive line disposed under the via or a second space between the lower conductive line and an adjacent lower conductive line; and
defining the plurality of characteristic values based on at least one of the first width or the first space and based on at least one of the second width or the second space.

16. A computer-implemented method of designing an integrated circuit, the method comprising:
receiving parameter data that includes a plurality of characteristic values with respect to one via in the integrated circuit;
receiving layout data that includes physical or geometric characteristics regarding various patterns included in a layout of integrated circuit, wherein the layout data includes a width value and a space value of a conductive line included in the layout;
extracting, by a processor, a parasitic element from the parameter data and the layout data; and
outputting a parasitic description file that includes parasitic resistances and parasitic capacitances of each of the conductive lines and vias that form one net of an integrated circuit.

17. The method of claim 16, wherein the parameter data includes a plurality of resistance values with respect to a via, wherein the plurality of resistance values are defined based on at least one of a width and a space of a conductive line connected to a via, and
extracting a parasitic element comprises selecting a via resistance from the plurality of resistance values in the parameter data, based on at least one of a width value and a space value of a conductive line in the layout data.

18. The method of claim 16, wherein the parameter data includes a plurality of capacitance values with respect to a via, wherein the plurality of capacitance values are defined based on at least one of a width and a space of a conductive line connected to a via, and
extracting a parasitic element comprises selecting a via capacitance from the plurality of capacitance values in parameter data, based on at least one of a width value and a space value of a conductive line in the layout data.

19. The method of claim 16, wherein the parasitic description file includes entire parasitic resistances and capacitances corresponding to one net of the integrated circuit.

20. The method of claim 16, further comprising:
receiving timing data;
receiving the parasitic description file;
performing a timing analysis based on at least one of a via resistance selected from the plurality of resistance values or a via capacitance selected from the plurality of capacitance values, based on a width value and a space value of a conductive line included in the layout, wherein a value is obtained that is close to an interconnect delay that occurs in a semiconductor device manufactured based on the layout; and
outputting a timing report.
